(19) United States
(12) Patent Application Publication
(10) Pub. No.: US 2022/0053665 A1
(43) Pub. Date: Feb. 17, 2022

(54) COOLING SYSTEM FOR COOLING AN ELECTRONICS COMPONENT OF AN ELECTRICAL DEVICE

(71) Applicants: DEFOND ELECTECH CO. LTD, Guangdong (CN); DEFOND COMPONENTS LIMITED, Chai Wan (HK)

(72) Inventors: Tak Chuen Or, Chai Wan (HK); Cheng Chen Nieh, Chai Wan (HK); Chiu Keung Loong, Chai Wan (HK); Ming Hong Daniel Wong, Chai Wan (HK)

(21) Appl. No.: 17/398,672

(22) Filed: Aug. 10, 2021

(30) Foreign Application Priority Data
Aug. 12, 2020 (HK) 32020013606.9

(51) Int. Cl. H05K 7/20

(52) U.S. Cl. CPC H05K 7/20136

(57) ABSTRACT

A cooling system for use in cooling an electronics component within a housing of an electrical device, the cooling system including:

a shape change device configured for variable arrangement between at least one of a first shape configuration and a second shape configuration; and
a control module configured for communicating at least one control signal to the shape change device so as to control operation of the shape change device;
wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

### TECHNICAL FIELD

The present invention relates to devices and methods for effecting cooling of electronics components in electrical appliances such as power tools, personal computers and the like.

### BACKGROUND OF THE INVENTION

Electrical devices such as electric power tools, personal computers and the like contain certain electronic components that tend to experience heat during operation of the electrical device. Cooling fans and the like are typically used to generate airflow within the device housing to effect cooling however certain problems are perceived to exist in this regard. Firstly, undesirable noise (e.g. humming) may be produced due to the high frequency operation of the electrical-mechanical components of the cooling fan. Further, cooing fans may not provide optimal and effective cooling of the most heated electronic components in the housing as it may not be practical for the cooling fan to be mounted in suitably close proximity to the heated electronics component being cooled.

### SUMMARY OF THE INVENTION

The present invention seeks to alleviate at least one of the above-described problems.

The present invention may involve several broad forms. Embodiments of the present invention may include one or any combination of the different broad forms herein described.

In one broad form, the present invention provides a cooling system for use in cooling an electronics component within a housing of an electrical device, the cooling system including:

a shape change device configured for variable arrangement between at least one of a first shape configuration and a second shape configuration; and

a control module configured for communicating at least one control signal to the shape change device so as to control operation of the shape change device;

wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

In another broad form, the present invention provides a pump system for use in pumping a fluid, the pump system including:

a shape change device configured for variable arrangement between at least one of a first shape configuration and a second shape configuration; and

a control module configured for communicating at least one control signal to the shape change device so as to control operation of the shape change device;

wherein responsive to the at least one control signal being received by the shape change device from the control module, the shape change device is configured to be variably arranged between the first and second shape configurations whereby said variable arrangement of the shape change device between the first and the second shape configurations is configured to force the fluid from a first position to a second position.

In yet another broad form, the present invention provides a shape change device for use with a cooling system to cool an electronics component within a housing of an electrical device, the cooling system including a control module configured for communicating at least one control signal to the shape change device so as to effect variable arrangement of the shape change device between at least one of a first shape configuration and a second shape configuration wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

In yet another broad form, the present invention provides a method of cooling an electronics component within a housing of an electrical device, the method including steps of:

(i) providing a shape change device withing the housing configured for variable arrangement between at least one of a first shape configuration and a second shape configuration; and

(ii) providing a control module configured for communicating at least one control signal to the shape change device so as to control operation of the shape change device;

wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

Preferably, the shape change device may be shaped and dimensioned to substantially complement a shape and dimensions of the electronics component being cooled.

Typically, the shape change device may include an elongate arm and wherein the elongate arm is configured to bend or change curvature shape when it is variably arranged between the first and second configurations in response to shape change device receiving the at least one control signal from the control module.

Typically, the shape change device may include a three-dimensional body and wherein a wall of the three-dimensional body is configured for folding, bending or concertinaed type movement to compress or expand the three-dimensional body when the shape change device is variably arranged between the first and second configurations in response to shape change device receiving the at least one control signal from the control module.

Typically, the shape change device may include a coil spring type body and wherein the coil spring type body is configured for compressive and expansive movement when the shape change device is variably arranged between the first and second configurations in response to shape change device receiving the at least one control signal from the control module.

Preferably, responsive to the one or more control signals generated by the control module, the shape change device is configured to oscillate between the first and second shape configurations in a predetermined manner to generate airflow relative to the electronics component.

Preferably, the at least one control signal communicated to the shape change device from the control module for controlling operation of the shape change device may include at least one of a voltage signal and a light signal applied directly or indirectly to the actuating material layer of the shape change device.

Typically, the electronics component may include at least one of a semiconductor, a switch component and a heatsink.

Preferably, at least one portion of the shape change device may include an actuating material layer configured to undergo variable arrangement between the first and second shape configurations in response to the at least one control signal being received by the actuating material layer of the shape change device.

Preferably, the actuating material layer may include nickel hydroxide-oxyhydroxide.

Preferably, the at least one portion of the shape change device may include a supporting material layer bonded to the actuating material layer for supporting the actuating material layer, whereby said supporting material layer is configured to change shape with the actuating material layer by urging of the actuating material layer.

Preferably, the supporting material layer may include an electrically conductive material such as nickel, copper, copper alloy with finishing of tin, silver or gold.

Preferably, the supporting material layer may be bonded to the actuating material layer by anodic electrodeposition.

Preferably the present invention may include a solution encapsulated within a reservoir, said reservoir being located adjacent to the actuating material layer and said reservoir being configured to allow for communication of water molecules from the actuating material layer in to the solution in the reservoir when a light signal is received by the actuating material layer from the control module so as to effect variable arrangement of the shape change device from the first shape configuration in to the second shape change configuration. Also preferably, the solution may include an electrolyte solution. Also preferably, the electrolyte solution may include an alkaline solution such as sodium hydroxide.

Preferably, at least one electrical connection terminal may be coupled to and in electrical communication with the supporting material layer.

Preferably, the at least one portion of the shape change device may include a plurality of actuating material layers having first sides bonded to corresponding supporting material layers, said plurality of actuating material layers having second sides that are electrically separated by at least one electrically insulating material, said reservoir encapsulating the solution being disposed between the second sides of the plurality of actuating material layers, said reservoir being configured to allow for communication of water molecules desorbed from each of the plurality of actuating material layers in to the solution in the reservoir in response to the light signal being received by the plurality of actuating material layers from the control module so as to effect variable arrangement of the shape change device from the first shape configuration in to the second shape change configuration.

Preferably, the at least one portion of the shape change device may be configured such that the actuating material layer undergoes varying degrees of shape change along its length in response to receiving the at least one control signal from the control module.

Preferably, the actuating material layer may be configured with varying shape and/or dimensions along its length so that it undergoes varying degrees of shape change along its length in response to receiving the at least one control signal from the control module.

### BRIEF DESCRIPTION OF THE DRAWINGS

The present invention will become more fully understood from the following detailed description of a preferred but non-limiting embodiments thereof, described in connection with the accompanying drawings, wherein:

FIGS. 1-4 show a bottom view of a support frame of a cooling system shaving a plurality of elongate arm-like shape change devices mounted thereon whereby the support frame may be fitted within a housing of an electrical device so that the shape change devices may effect cooling of an electronic component in the housing in accordance with an embodiment of the present invention;

FIG. 5 shows a rear view of the support frame of FIGS. 1-4 without the shape change devices mounted thereon in accordance with an embodiment of the present invention;

FIG. 6 shows a front view of the support frame of FIGS. 1-4 without the shape change devices mounted thereon in accordance with an embodiment of the present invention;

FIG. 7 shows a magnified view of one of the elongate arm-like shape change devices configured for mounting on the support frame in FIGS. 1-4 according to an embodiment of the present invention;

FIGS. 8-9 show a shape-change device having a three-dimensional body variably arranged in an expanded and compressed concertina shape configuration respectively in accordance with another embodiment of the present invention;

FIGS. 10-11 show a shape-change device having a three-dimensional body variably arranged in an expanded and compressed shape configuration respectively whereby the sidewalls of the shape change device are configured for folding, curving or bending in accordance with another embodiment of the present invention; and

FIGS. 12-13 show a shape-change device having a coil spring body arranged in an expanded and compressed shape configuration respectively whereby in accordance with another embodiment of the present invention.

### DETAILED DESCRIPTION OF PREFERRED EMBODIMENTS

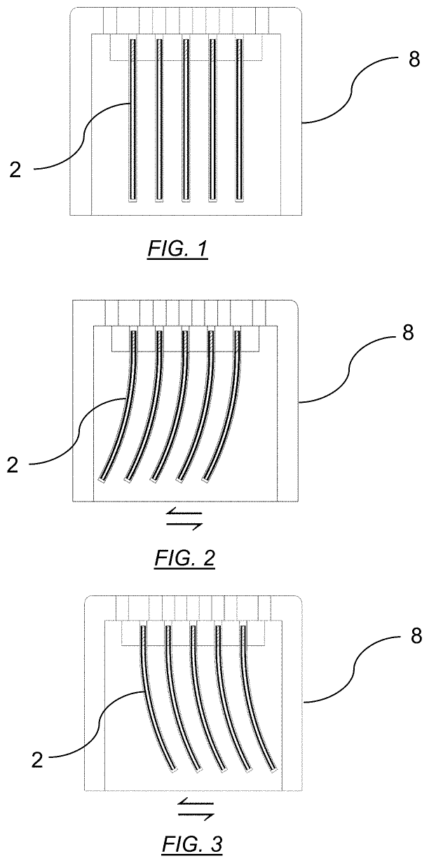

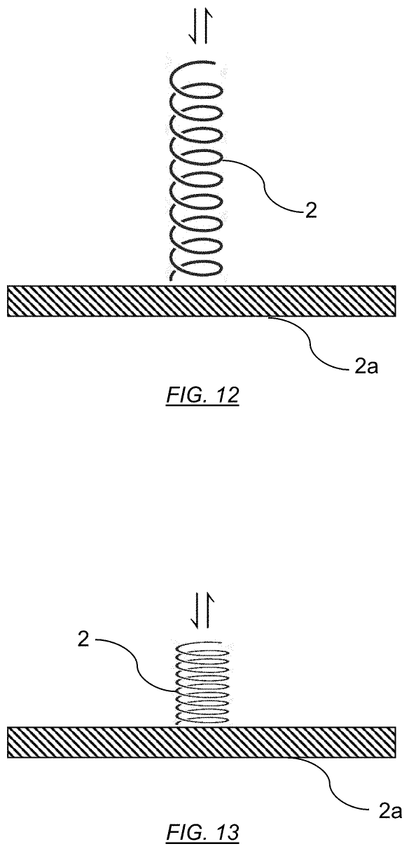

Preferred embodiments of the present invention will now be described herein with reference to FIGS. 1 to 13. The embodiments are directed towards a cooling system (1) including a shape change device (2) configured for cooling an electronics component in a housing of an electrical device, as well as the shape change device itself and a method of using same to effect cooling. By way of example, the electrical device may for instance include an electric power tool or a personal computer which may typically comprise passive or active electrical/electronic components within respective housings which tend to generate relatively high levels of heat within the housings. Such components may typically comprise semiconductor components, heatsinks, power switching circuitry components and the like. It would be appreciated and understood embodiments of the present invention may of course be used with other types of electrical devices such as gardening tools and home appliances. Other embodiments of the present invention may further be suitably adapted for use as a fluid pump for generating flow of a fluid (e.g. air) for ventilation or cooling purposes even where heat dissipation/transfer may not be a primary concern.

In a first embodiment, a cooling system is provided for use in cooling an electronics component within a housing of an electrical device. The cooling system includes at least one shape change device (2) that is configured for variable arrangement between at least one of a first shape configuration (e.g. as shown in FIG. 1) and a second shape configuration (e.g. as shown in FIG. 2). A control module (3) is configured for communicating control signals to the shape change device (2) so as to control operation of the shape change device (2). In response to the at least one control signal being received by the shape change device (2) from the control module (3), the shape change device (2) is configured to be variably arranged between the first and second shape configurations whereby said variable arrangement of the shape change device (2) between the first and the second shape configurations is causes an airflow to be generated to displace heated air proximate to the electronics component away from the electronics component so as to effect cooling of the electronics component.

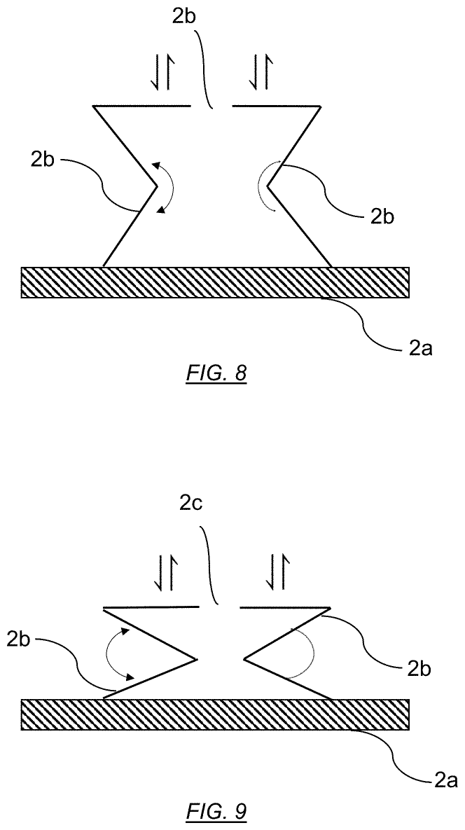

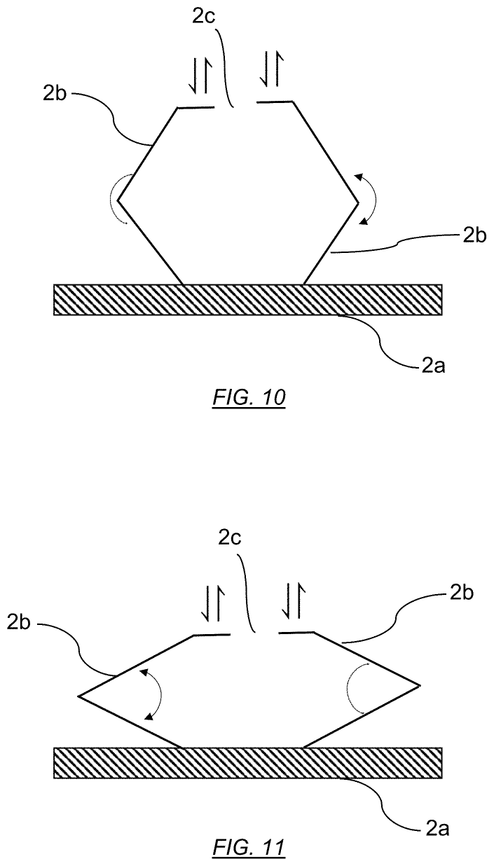

In these exemplary embodiments, the shape change device (2) may be mounted on a base (2a) and formed in a variety of possible shape configurations with varying dimensions so as to complement shapes and dimensions of different types of electronics component being cooled. By virtue of the complementary shape and dimensions, the shape change device (2) may lend itself more readily to mounting upon, insertion, or otherwise location in closer proximity to the electronics component being cooled so as maximise the cooling effect produced by the shape change device upon the electronics component in question. For instance, in certain embodiments, the shape change device (2) may be formed in a relatively elongate arm-like or coil spring type shape such as is shown in FIGS. 1-4, 7 and 12-13 respectively so as to be suited to complement an elongate electronics component, or, for location within a relatively elongate space (e.g. within a wiring conduit) within the housing. In the elongate arm embodiment, it is configured to bend, change curve or curl when it is variably arranged between the first and second configurations in response to the shape change device receiving the at least one control signal from the control module (3). In the coil spring body embodiment, it is configured for compressive and expansive movement along an elongate axis of the coil spring body when the shape change device is variably arranged between the first and second configurations in response to shape change device receiving the at least one control signal from the control module (3). The coil spring body and elongate arm-like body embodiments may be further shaped or textured on their outer surfaces so that the shape change devices may be better adapted to forcing/driving air when the bodies are moved between their first and second configurations. Alternately, the body of the shape change device may be formed in a three-dimensional shape similar to that shown in FIGS. 8-11 which may for instance be lend itself particularly well suited for complementing a planar surface of a heatsink or the like when mounted thereon. In such an embodiment, sidewalls (2b) of the three-dimensional body are formed from shape change devices that are configured for concertinaed type movement as shown in FIGS. 8-9, or, folding, curving or bending as shown in FIGS. 10-11. It can be seen from the embodiments in FIGS. 8-10 that one or more openings (2c) may be disposed in the top surfaces of the three-dimensional bodies which allows air within the housing to flow in to the space within the three-dimensional body when the three-dimensional body has been arranged in to its relatively expanded shape configuration as shown in the FIGS. 8 and 10. When the sidewalls (2b) of the respective shape change devices fold, curve or bend to compress the internal space within the three-dimensional bodies in response to control signal activation, the air within the three-dimensional bodies is expelled outwardly of the three-dimensional bodies via the openings in the top surfaces. The process repeats as the three-dimensional bodies are expanded and compressed by urging of the shape change device sidewalls (2b). Conveniently, as the shape change devices may be configured to complement shape profiles and dimensions of specific components of the electrical device being cooled, these embodiments may be configured for closer mounting on or in proximity to the specific electronics component or closed space within which the electronics component is located. Accordingly, by virtue of this closer proximity and complementary shape and dimensions, such devices may provide for a more focused and effective localised cooling of the electronics component in comparison to for instance a cooling fan within the housing which may not effectively target the electronics component for cooling.

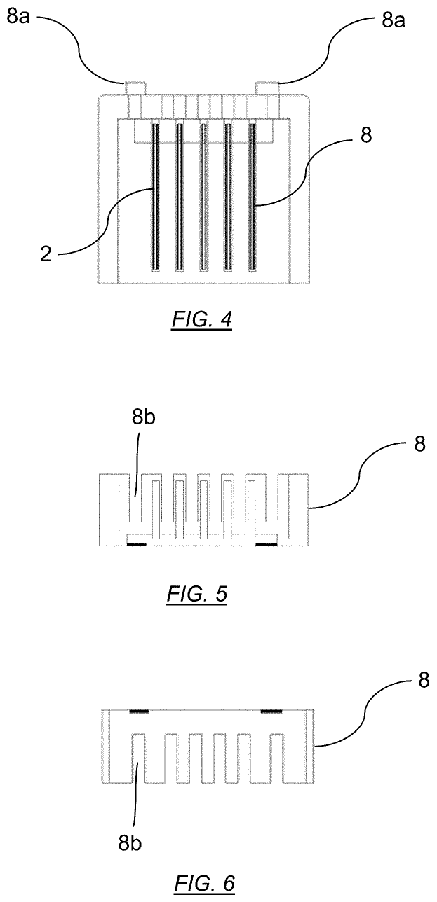

In these embodiments, the control module (3) is configured for generating and communicating control signals to the shape change device whereby the shape change device responsive to the received control signals, the shape change device (2) oscillates between the first and second shape configurations in a predetermined manner (e.g. according to a predetermined frequency, according to a predetermined number of oscillations, and/or at a predetermined amplitude of movement). This oscillatory movement of the shape change device (2) may provide a continuous and on-going flow of heated air proximate to the electronics component away from the electronics component to effect cooling. The airflow movement may include the heated air proximate to the heated electronics component being urged outwardly of the housing via an air vent, or in to contact with a heatsink or other heat transfer device. The airflow movement caused by the shape change device (2) may also draw in relatively cool air in to the housing in to proximity to the electronic component via an air inlet vent. In certain embodiments the shape change device may be configured to vary in to more than two different shape configuration as can be seen in FIGS. 1 to 3 were the shape change devices are straight in a first shape configuration (as shown in FIG. 1), curved to one side in a second shape configuration (as shown in FIG. 2), and, curved to an opposite side in a third shape configuration (as shown in FIG. 3). The control module may be configured to output different control signals to the shape change device and whereby responsive to receiving the control signals the shape change device is configured to vary in a shape according to the sequence of three (or more) different shape configurations depicted in FIGS. 1-3 in oscillatory motion.

In these embodiments, the at least one control signal generated by the control module (3) for controlling operation of the shape change device (2) includes a voltage signal and/or a light signal applied directly or indirectly to the actuating material layer of the shape change device (2). The voltage signal may be generated by a DC voltage source and applied across an electrical contact point of the shape change device (2) and a reference terminal. The light signal may for instance include a light signal in the visible light spectrum produced by any suitable light emitting device (e.g. an LED module). The light emitting device may be directed towards the actuating layer via a light guide element such as an optical fiber in combination with an optical lens. The degree of shape change that is produced by the shape change device may be determined by properties and characteristics of the control signal.

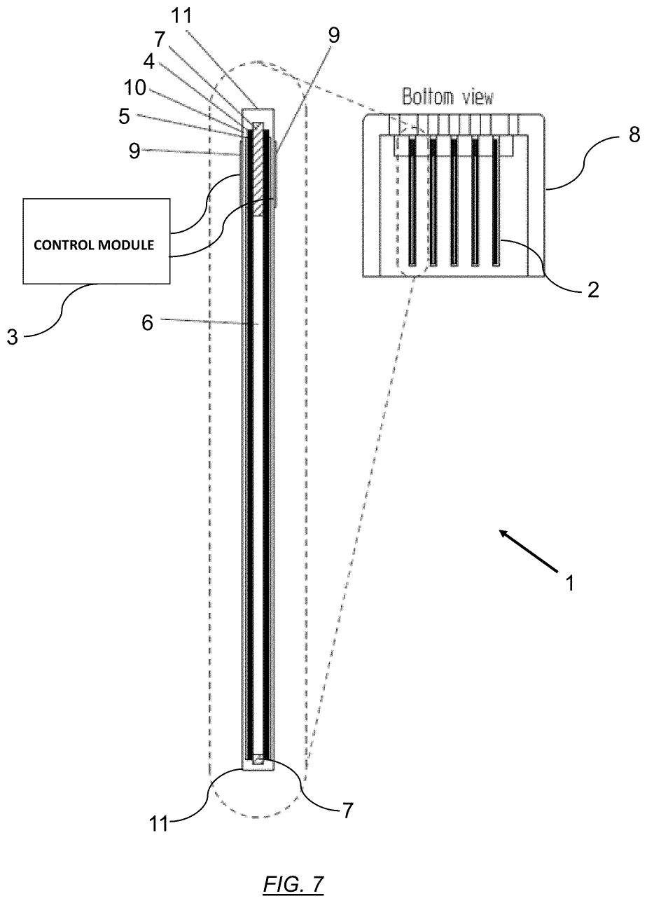

Referring to FIG. 7. at least one portion of the shape change device (2) includes an actuating material layer (4) configured for undergoing variable arrangement between the first and second shape configurations in response to the at least one control signal being received by the actuating material layer (4). In this embodiment, the actuating material layer (4) includes nickel hydroxide-oxyhydroxide. A supporting material layer (5) is bonded to the actuating material layer (4) for supporting the actuating material layer (4). The supporting material layer (5) is configured to change shape with the actuating material layer (4) by urging of the actuating material layer (4) as the actuating material layer (4) varies its shape. In these embodiments, the supporting material layer (5) includes a conductive material such as nickel, copper, copper alloy with finishing of tin, silver or gold. The actuating material layer (4) may be bonded to the supporting material layer (5) using any suitable process including for instance anodic electrodeposition. In certain embodiments, an additional layer of a conductive metal such as gold film may be bonded to both the nickel hydroxide-oxyhydroxide and nickel materials as a thin intermediate layer. The gold layer may assist in protecting the nickel layer from dissolution during the electroplating of Ni((H)2-NiOOH. By way of example, in these embodiments the width and thickness of the Ni(OH)2-NiOOH material use in the actuating material layer (4(was around 4 mm and 1.0-1.4 μm respectively. The thickness of the nickel material in the supporting material layer (5) may be suitably determined based on the amount of force applied by the actuating material layer (4) when the actuating material layer (4) changes shape in response to control signals applied to it.

An electrical contact terminal (9) is disposed on the supporting material layer (5) via which the voltage control signal may be applied by the control module (3) via connecting wires. As the supporting material layer (5) is nickel, the voltage is indirectly applied to the actuating material layer (4) which is in electrical communication with the nickel supporting material layer (4). Responsive to the voltage control signal being applied, the actuating material layer (4) varies in shape from the first shape configuration to the second shape configuration. In other embodiments the voltage may be applied directly to the actuating material layer (4). In these embodiments, and to provide some example of the voltage control signal which may be utilised, when a control signal of approximately 0.6V is applied to the actuating material layer (4), the actuating material layer (4) varies in its shape from the first shape configuration in to the second shape configuration. When the control signal fails below 0.6 V, the actuating material layer (4) undergoes reversal in its shape from the second shape configuration back in to the first shape configuration.

A fluid reservoir (6) may also be located adjacent to the actuating material layer (4) which encapsulates an electrolyte solution such as sodium hydroxide. The walls of the reservoir (6) which encapsulate the electrolyte solution may include a flexible membrane. The reservoir (6) is configured such that when a light control signal is directed at the nickel hydroxide-oxyhydroxide material of the actuating material layer (4), intercalated water molecules disposed between layers in the crystal lattice structure of the nickel hydroxide-oxyhydroxide are desorbed from the nickel hydroxide-oxyhydroxide and pass in to the electrolyte solution in the adjacent reservoir (6). In response to the removal of the water molecules form the nickel hydroxide-oxyhydroxide, the actuating material layer (4) undergoes contraction and changes from its first shape configuration in to its second shape configuration—that is, in this case the actuating material layer contract and varies from a straight shape configuration in to a curved shape as shown in the accompanying drawings. Conversely, when the light control signal is terminated the water molecules from the electrolyte solution in the reservoir (6) are able to be reversibly absorbed back in to the nickel hydroxide-oxyhydroxide of the actuating material layer (4) which then reverts from the second shape configuration (i.e. the curved configuration) back in to the first shape configuration (i.e. the straight configuration). In these embodiments, the actuating material layer may be responsive to light control signal of intensity of around 5 to 100 mW/cm2 in order to vary between the first and second shape configurations. Whilst nickel hydroxide-oxyhydroxide is used to form the actuating material layer (4) in these example embodiments, it is conceivable that other materials with similar turbotrain crystal structures may also be used in alternate embodiment to produce similar functionality.

In certain embodiments, the at least one portion of the shape change device (2) includes a pair of actuating material layers (4) arranged in parallel. The pair of actuating material layers (4) have first sides bonded to corresponding supporting material layers (5) and second sides that are electrically separated by an insulating material (7). The reservoir (6) encapsulating the electrolyte solution is located between the second sides of the pair of actuating material layers (5) and is configured to allow for communication of water molecules desorbed from each of the actuating material layers (4) in to the electrolyte solution in the reservoir (6) in response to the light control signal being received by the actuating material layers (4) from the control module (3) so as to effect variable arrangement of the shape change device from the first shape configuration in to the second shape change configuration. The overall device structure in this embodiment is symmetrical in appearance and function although this need not necessarily be the case. The device could be asymmetrical in this regard if so desired. As can be seen from FIGS. 1-4, a series of identical shape change devices may be mounted on a support frame (8) in side-by-side fashion, for instance by compression fitting engagement within receiving slots (8b) in the support frame which can then be rigidly mounted as a single cooling unit within the housing. Each of the plurality of shape change devices (2) may be configured to receive identical control signals via input electrical terminals (8a) disposed on the support frame (8) simultaneously from the control module so that they may be operated in a synchronised manner. Sealing ends (11) which may include dielectric material (10) are disposed at ends of the shape change devices.

In certain embodiments, the at least one portion of the shape change device is configured such that the actuating material layer (4) undergoes varying degrees of shape change along its length in response to receiving the at least one control signal from the control module (3). Yet further, the actuating material layer (4) is configured with varying shape and/or dimensions along its length so that it undergoes varying degrees of shape change along its length in response to receiving the at least one control signal from the control module (3).

It would be understood that in yet other embodiments of the present invention, the above described embodiments may be configured for use as a fluid pump to pump for instance liquid or gas within a closed environment by variable arrangement of the shape change device between first and second shape configurations. In yet other embodiments, the above-described embodiments may be utilised for effecting cooling in other contexts which are not necessarily limited to electronics components of electrical devices.

It will be apparent that embodiments of the present invention may provide at least one advantage over existing technologies in the technical field. For instance, as the shape change device may be configured to complement a shape and dimensions of a specific electronics component, the cooling system may be optimised to transfer heated air more effectively and in a more targeted manner from the proximity of the electronics component compared to use of a cooling fan for instance. Further, as the shape change device of the cooling system may be actuated for oscillatory movement at a relatively low frequency, this alleviates undesirable noise that accompanies existing cooling devices such as cooling fans and the like. Further, as the shape change device may be actuated wirelessly for shape variation by use of light control signals, this obviates the need for control wiring extending from the control module to the shape change device and at the same time alleviates potential points of failure associated with wired connections as used in existing technologies. Yet further, the use of a nickel layer as the supporting material layer of the shape change device is advantageous as this is a relatively cheap material with suitably robust properties to structurally support the actuating material layer of the shape change device.

It is noted that, when a component is described to be “fixed”, “coupled”, “attached”, “engaged”, “connected” or the like to another component, it may be directly fixed to the another component or there may be an intermediate component unless expressly or implicitly stated to the contrary. When a component is described to be “disposed” on or in another component, it can be directly disposed on or in the another component or there may be an intermediate component unless expressly or implicitly stated to the contrary.

Unless otherwise specified, all technical and scientific terms have the ordinary meaning as commonly understood by persons skilled in the art. The terms used in this disclosure are illustrative rather than limiting. The term “and/or” used in this disclosure means that each and every combination of one or more associated items listed are included.

Those skilled in the art will appreciate that the invention described herein is susceptible to variations and modifications other than those specifically described without departing from the scope of the invention. All such variations and modification which become apparent to persons skilled in the art, should be considered to fall within the spirit and scope of the invention as broadly hereinbefore described. It is to be understood that the invention includes all such variations and modifications. The invention also includes all of the steps and features, referred or indicated in the specification, individually or collectively, and any and all combinations of any two or more of said steps or features.

The reference to any prior art in this specification is not, and should not be taken as, an acknowledgment or any form of suggestion that that prior art forms part of the common general knowledge.

1. A cooling system for use in cooling an electronics component within a housing of an electrical device, the cooling system including:
a shape change device configured for variable arrangement between at least one of a first shape configuration and a second shape configuration; and
a control module configured for communicating at least one control signal to the shape change device so as to control operation of the shape change device;
wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

2. A cooling system of claim 1 wherein the shape change device is shaped and dimensioned to substantially complement a shape and dimensions of the electronics component being cooled.

3. A cooling system as claimed in claim 1 wherein the shape change device includes an elongate arm and wherein the elongate arm is configured to bend or change curvature shape when it is variably arranged between the first and second configurations in response to shape change device receiving the at least one control signal from the control module.

4. A cooling system as claimed in claim 1 wherein the shape change device includes a three-dimensional body and wherein a wall of the three-dimensional body is configured for folding, bending or concertinaed type movement to compress or expand the three-dimensional body when the shape change device is variably arranged between the first and second configurations in response to shape change device receiving the at least one control signal from the control module.

5. A cooling system as claimed in claim 1 wherein the shape change device includes a coil spring type body and wherein the coil spring type body is configured for compressive and expansive movement when the shape change device is variably arranged between the first and second configurations in response to shape change device receiving the at least one control signal from the control module.

6. A cooling system as claimed in claim 1 wherein responsive to the one or more control signals generated by the control module, the shape change device is configured to oscillate between the first and second shape configurations in a predetermined manner to generate airflow relative to the electronics component.

7. A cooling system as claimed in claim 1 wherein the at least one control signal communicated to the shape change device from the control module for controlling operation of the shape change device includes at least one of a voltage signal and a light signal applied directly or indirectly to the actuating material layer of the shape change device.

8. A cooling system as claimed in claim 1 wherein the electronics component includes at least one of a semiconductor, a switch component and a heatsink.

9. A cooling system as claimed in claim 1 wherein at least one portion of the shape change device includes an actuating material layer configured to undergo variable arrangement between the first and second shape configurations in response to the at least one control signal being received by the actuating material layer of the shape change device.

10. A cooling system as claimed in claim 9 wherein the actuating material layer includes nickel hydroxide-oxyhydroxide.

11. A cooling system as claimed in claim 9 wherein the at least one portion of the shape change device includes a supporting material layer bonded to the actuating material layer for supporting the actuating material layer, whereby said supporting material layer is configured to change shape with the actuating material layer by urging of the actuating material layer.

12. A cooling system as claimed in claim 11 wherein the supporting material layer includes an electrically conductive material such as nickel, copper, copper alloy with finishing of tin, silver or gold.

13. A cooling system as claimed in claim 11 wherein the supporting material layer is bonded to the actuating material layer by anodic electrodeposition.

14. A cooling system as claimed in claim 9 including a solution encapsulated within a reservoir, said reservoir being located adjacent to the actuating material layer and said reservoir being configured to allow for communication of water molecules from the actuating material layer in to the solution in the reservoir when a light signal is received by the actuating material layer from the control module so as to effect variable arrangement of the shape change device from the first shape configuration in to the second shape change configuration.

15. A cooling system as claimed in claim 14 wherein the solution includes an electrolyte solution.

16. A cooling system as claimed in claim 14 wherein the electrolyte solution includes an alkaline solution such as sodium hydroxide.

17. A cooling system as claimed in claim 11 wherein at least one electrical connection terminal is coupled to and in electrical communication with the supporting material layer.

18. A cooling system as claimed in claim 9 wherein the at least one portion of the shape change device includes a plurality of actuating material layers having first sides bonded to corresponding supporting material layers, said plurality of actuating material layers having second sides that are electrically separated by at least one electrically insulating material, said reservoir encapsulating the solution being disposed between the second sides of the plurality of actuating material layers, said reservoir being configured to allow for communication of water molecules desorbed from each of the plurality of actuating material layers in to the solution in the reservoir in response to the light signal being received by the plurality of actuating material layers from the control module so as to effect variable arrangement of the shape change device from the first shape configuration in to the second shape change configuration.

19. A cooling system as claimed in claim 9 wherein the at least one portion of the shape change device is configured such that the actuating material layer undergoes varying degrees of shape change along its length in response to receiving the at least one control signal from the control module.

20. A cooling system as claimed in claim 19 wherein the actuating material layer is configured with varying shape and/or dimensions along its length so that it undergoes varying degrees of shape change along its length in response to receiving the at least one control signal from the control module.

21. A pump system for use in pumping a fluid, the pump system including:
a shape change device configured for variable arrangement between at least one of a first shape configuration and a second shape configuration; and
a control module configured for communicating at least one control signal to the shape change device so as to control operation of the shape change device;
wherein responsive to the at least one control signal being received by the shape change device from the control module, the shape change device is configured to be variably arranged between the first and second shape configurations whereby said variable arrangement of the shape change device between the first and the second shape configurations is configured to force the fluid from a first position to a second position.

22. A shape change device for use with a cooling system to cool an electronics component within a housing of an electrical device, the cooling system including a control module configured for communicating at least one control signal to the shape change device so as to effect variable arrangement of the shape change device between at least one of a first shape configuration and a second shape configuration wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.

23. A method of cooling an electronics component within a housing of an electrical device, the method including steps of:
(i) providing a shape change device within the housing configured for variable arrangement between at least one of a first shape configuration and a second shape configuration; and
(ii) providing a control module configured for communicating at least one control signal to the shape change device so as to control operation of the shape change device;
wherein responsive to the at least one control signal being received by the shape change device from the control module, the shape change device is configured to be variably arranged between the first and second shape configurations whereby said variable arrangement of the shape change device between the first and the second shape configurations is configured to generate an airflow relative to the electronics component so as to effect cooling of the electronics component.
